(19) United States
(12) Patent Application Publication
(10) Pub. No.: US 2013/0200900 A1
(43) Pub. Date: Aug. 8, 2013

(54) MRI PHANTOM WITH A PLURALITY OF COMPARTMENTS FOR T1 CALIBRATION

(71) Applicants: Johannes Buurman, 's-Hertogenbosch (NL); Gregory Stanislaus Karczmar, Crete, IL (US); Devkumar Mustafi, Chicago, IL (US); Bo Peng, Buffalo Grove, IL (US); Marko Kresimir Ivancevic, Chicago, IL (US); Marieke Heisen, Dulvendrecht (NL)

(72) Inventors: Johannes Buurman, 's-Hertogenbosch (NL); Gregory Stanislaus Karczmar, Crete, IL (US); Devkumar Mustafi, Chicago, IL (US); Bo Peng, Buffalo Grove, IL (US); Marko Kresimir Ivancevic, Chicago, IL (US); Marieke Heisen, Dulvendrecht (NL)

(73) Assignee: KONINKLIJKE PHILIPS ELECTRONICS N.V., EINDHOVEN (NL)

(21) Appl. No.: 13/879,411

(22) PCT Filed: Oct. 4, 2011
(86) PCT No.: PCT/IB11/54348

§ 371 Date: Apr. 15, 2013

Related U.S. Application Data
(60) Provisional application No. 61/392,574, filed on Oct. 13, 2010.

(51) Int. Cl. G01R 33/58

(52) U.S. Cl. CPC G01R 33/583
USPC 324/322; 324/318; 600/411

(57) ABSTRACT

Disclosed herein is a magnetic resonance imaging calibration assembly in particular, for dynamic contrast—enhanced magnetic resonance imaging. An exemplary magnetic resonance imaging calibration assembly according to the present disclosure can comprise a subject receptacle for receiving at least a portion of a subject. The exemplary magnetic resonance imaging calibration assembly can further comprise a plurality of phantom compartments, each of which can contain a calibration phantom with a predetermined known T relaxation time. The plurality of phantom compartments can be attached to the subject receptacle in different ways. For example, according to some exemplary embodiments of the 10 present invention, the phantom compartments are separate compartments attached or fixed onto the subject receptacle. According to other exemplary embodiments, the phantom compartments can be formed at least partially by the subject receptacle. The phantom can be for a T1 calibration making use of its known T1.

### TECHNICAL FIELD

The invention relates to magnetic resonance imaging, in particular dynamic contrast-enhanced magnetic resonance imaging.

### BACKGROUND OF THE INVENTION

In Dynamic Contrast-Enhanced MRI (DCE-MRI), a contrast agent containing a substance which can be detected via magnetic resonance imaging is injected into a subject. For example, gadolinium containing compounds may be injected into a patient's blood stream, and a time series of magnetic resonance imaging images is made using a T1-weighted protocol. The time series, typically started before injection and continuing for several minutes, shows the spread of contrast agent by means of the changed T1 caused by the Gadolinium.

DCE-MRI is very useful in diagnosing certain medical conditions or in evaluating the effectiveness of a therapy. If a time series of magnetic resonance images are made using a T1-weighted protocol, gadolinium based compounds may be used to illustrate the evaluate or measure vascularization of a region of a subject. For example, the technique may be used to show neuvascularization caused by tumor growth.

### SUMMARY OF THE INVENTION

The invention provides for a magnetic resonance imaging calibration assembly, a magnetic resonance imaging system, a computer program product and a computer-implemented method in the independent claims. Embodiments are given in the dependent claims.

A quantitative analysis of the spread of the contrast agent through a subject however is made difficult by the fact that the signal change in a voxel due to the contrast agent is not a simple (e.g. linear) function of the concentration of contrast agent in that voxel.

One area of application of this invention is MRI of the breast. Increased uptake of contrast agent in breast cancer tissue shows increased blood flow and/or capillary permeability which is indicative of, amongst others, breast cancer. The example of breast magnetic resonance imaging is used here, however embodiments of the invention are not limited to breast magnetic resonance imaging.

There are presently two main approaches towards analysis of DCE-MRI, and several hybrid methods. The first is phenomenological. Here, clinicians simply observe the signal intensity as a function of time. Based on the structures seen as well as heuristics on the MRI signal as a function of time, radiologists draw conclusions on what is seen. Physicians typically observe that, after an initial uptake (measured 2-3 minutes after contrast injection), the signal may increase further, stabilize or decrease (called types 1, 2 and 3, respectively), where type 3 is strongly correlated with malignancy and type 1 is somewhat correlated with benign conditions. Later publications try to put thresholds, both on the initial uptake and on the distinction between the types, but these do not generalize from one scanner and protocol to another. Present state of the art is to leave it to the observer to pick thresholds for his or her scanner and scanner protocol, hence the total lack of quantitative recommendations in Bi-Rads. This is particularly cumbersome for sites that have scanners of different manufacturers, because they may need different thresholds for these scanners. This is also a problem for Breast MRI CAD systems, which contain thresholds on relative enhancement which depend on the scanner and protocol.

The second approach to quantitative DCE-MRI is pharmacokinetic modeling. Here, an attempt is made to estimate contrast concentrations in vessels and tissue from signal intensities and subsequently to derive parameters in a tissue model from these concentrations. This approach has the promise of being more quantitative, but imposes special requirements on the scanner protocol. For instance, a reference scan is required to measure the T1 of the tissue without contrast. A high temporal resolution of the scan (better than one image every 40-60 seconds) is required to measure blood flow and the arterial input function, which is required to estimate the tissue parameters accurately. Current clinical practice for the breast does not meet these requirements (no reference scan, one image every 1-2 minutes).

It is therefore advantageous to develop a way to describe signal intensity as a function of time in DCE-MRI quantitatively, i.e. that is independent of scanner and scanner protocol. In particular, we want to describe the contrast uptake of DCE-MRI of the breast in a way that is independent of scanner and scanner protocol.

As described above, the two current approaches are:
(1) Phenomenological, which requires the user to interpret the curves and compare them to other curves that were acquired with the same protocol. Breast MRI CAD systems, like Confirma's CADStream and Invivo's DynaCAD, require thresholds to be set on relative enhancements measures. These thresholds today are dependent on the scanner type and protocol.
(2) Pharmacokinetic modeling, might offer a way around this, but imposes requirements on the scanning protocol: high temporal resolution, T1 calibration scan.

The phenomenological approach, described above, suffers from arbitrary thresholds that users have to choose. What is more, these thresholds are different between one scanner and scanner protocol and another.

Pharmacokinetic modeling requires scans with a temporal resolution that is significantly higher than today's clinical practice. Also, a special scan is required to estimate the pre-contrast T1 of the tissue.

Embodiments of the invention may address these or other technical problems by providing a phantom near the breast that has several compartments, each containing a different, known contrast agent concentration, dissolved in a known medium, e.g. water or air-bubble free agar. The use of a calibration phantom during the acquisition of magnetic resonance data may allow the calculation of contrast agent concentration maps. The actual concentration of the contrast agent is calculated empirically as opposed to simply examining intensity in an image. Furthermore such a technique does not require the high temporal resolution that is required for Pharmacokinetic modeling.

During implementation of an embodiment of the method the intensity values for the compartments of the phantom is obtained:

A simple way to get these is to have the user draw regions of interest manually. Intensity values and standard deviations can then be derived by averaging the pixel values in each ROI.

Software can also be used to detect the phantom automatically, an embodiment of an algorithm is:

Detect and exclude the body from the scan, e.g. by thresholding any of the acquired volumes and doing a propagation from the posterior side, invert and multiply with the original image.

Detect the remaining objects, e.g. by thresholding the remaining data and measuring size, shape and position of the resulting objects and comparing with model data.

Remove spurious detections by testing the objects size, shape and position against a model.

The advantage of this method is that contrast agent uptake can now be measured in a scanner and scan protocol independent way. This is in particular useful for Breast MRI CAD systems, where thresholds are set on relative enhancement, which result in a classification of pixels. Presently, these thresholds depend on the scanner type and protocol. Using this method, these thresholds only need to be found once for all scanner types and protocols.

Clinically, the patient may be scanned with the phantom present. The scanning protocol is exactly the same protocol that would have been used without the phantom. If the proton density of the phantom is different than that of the subject, a fast scan to measure proton density in some cases.

For other calibration scans—including T1 measurements could be included. In case of T1 measurements (using a variable flip angle (VFA) approach or otherwise) the phantoms could be used to refine the T1 measurements, for example—the VFA T1 data from the phantom could be used to correct the flip angle that is used.

A computer-readable storage medium as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM) memory, Read Only Memory (ROM) memory, an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network.

Computer memory is an example of a computer-readable storage medium. Computer memory is any memory which is directly accessible to a processor. Examples of computer memory include, but are not limited to: RAM memory, registers, and register files.

Computer storage is an example of a computer-readable storage medium. Computer storage is any non-volatile computer-readable storage medium. Examples of computer storage include, but are not limited to: a hard disk drive, a USB thumb drive, a floppy drive, a smart card, a DVD, a CD-ROM, and a solid state hard drive. In some embodiments computer storage may also be computer memory or vice versa.

A computing device as used herein refers to any device comprising a processor. A processor is an electronic component which is able to execute a program or machine executable instruction. References to the computing device comprising “a processor” should be interpreted as possibly containing more than one processor. The term computing device should also be interpreted to possibly refer to a collection or network of computing devices each comprising a processor. Many programs have their instructions performed by multiple processors that may be within the same computing device or which may even distributed across multiple computing device.

A ‘user interface’ as used herein is an interface which allows a user or operator to interact with a computer or computer system. A user interface may provide information or data to the operator and/or receive information or data from the operator. The display of data or information on a display or a graphical user interface is an example of providing information to an operator. The receiving of data through a keyboard, mouse, trackball, touchpad, pointing stick, graphics tablet, joystick, gamepad, webcam, headset, gear sticks, steering wheel, pedals, wired glove, dance pad, remote control, and accelerometer are all examples of receiving information or data from an operator.

‘Magnetic Resonance (MR) data’ as used herein encompasses the recorded measurements of radio frequency signals emitted by atomic spins by the antenna of a Magnetic resonance apparatus during a magnetic resonance imaging scan. A Magnetic Resonance Imaging (MRI) image is defined herein as being the reconstructed two or three dimensional visualization of anatomic data contained within the magnetic resonance imaging data. This visualization can be performed using a computer.

In one aspect the invention provides for a magnetic resonance imaging calibration assembly. The magnetic resonance imaging calibration assembly comprises a subject receptacle for receiving at least a portion of a subject. The magnetic resonance imaging calibration assembly further comprises a plurality of phantom compartments. Each of the plurality of phantom compartments contains a calibration phantom with a predetermined T1 relaxation time. The plurality of phantom compartments is attached to the subject receptacle. The plurality of phantom compartments may be attached to the subject receptacle in several different ways. In some embodiments the phantom compartment are separate compartments that are attached or fixed onto the subject receptacle. In other embodiments the phantom compartments are formed at least partially by the subject receptacle.

In other words the magnetic resonance imaging calibration assembly comprises a subject receptacle for holding or supporting at least a portion of the subject and multiple phantom compartments. Each of the phantom compartments may contain a calibration phantom that has a different predetermined T1 relaxation time. This embodiment is advantageous because by holding calibration phantoms with different predetermined T1 relaxation times the magnetic resonance imaging calibration assembly can be used for calibrating T1 weighted magnetic resonance images. This may be particularly useful for calibrating magnetic resonance images acquired before and after a T1 relaxation time contrast agent has been injected into a subject.

In another embodiment each of the plurality of phantom compartments has a distinct cross section. Another way of wording this is that each of the plurality of phantom compartments has a cross section which is distinguishable or identifiable with respect to the other cross sections. This is advantageous because if a T1 weighted magnetic resonance image is constructed each of the phantom compartments will be easily identifiable in the magnetic resonance image purely by the cross sections of the phantom compartments. The various profiles may be detected using image recognition; several different techniques may be used: computing the area, perimeter, number of corners, or by template matching.

In another embodiment in at least one of the plurality of phantom compartments comprises a tube. This is advantageous because a tube may be filled with a calibration phantom and wrapped around or mounted on the subject receptacle.

In another embodiment the at least one of the plurality of phantom compartments contains at least two sub-compartments. At least one sub-compartment is not filled with the T1 relaxation time calibration phantom. This is advantageous because the identification of sub-compartments that are not filled with T1 relaxation time calibration phantom may provide a means of identifying each of the phantom compartments.

In another embodiment each of the tubes forms a closed circuit that may be advantageous for location in multiple slice magnetic resonance imaging data. If a phantom compartment is not continuous to perform a closed circuit then there may be slices where the phantom compartment is not visible in the magnetic resonance imaging image.

In another embodiment the subject support further comprises a radio frequency coil for acquiring magnetic resonance data. This embodiment may be advantageous because incorporating the radio frequency coil into the subject support may save space and allow easier integration of the magnetic resonance imaging calibration assembly into a magnetic resonance imaging system.

In another embodiment the magnetic resonance imaging calibration assembly further comprises a biopsy apparatus for performing a biopsy of a biopsy zone of the subject. The biopsy apparatus has a known geometry relative to the plurality of phantom compartments. This embodiment may be advantageous because when a magnetic resonance imaging image is constructed the anatomy of the subject relative to the phantom compartments is known. Likewise, if the biopsy apparatus is integrated into the magnetic resonance imaging calibration assembly then the geometry of the biopsy apparatus may be known relative to the phantom compartments also. For instance the biopsy apparatus may have a needle which is inserted into a subject using a mechanism.

In another embodiment the predetermined T1 relaxation time is equivalent to a known T1 contrast agent concentration. For instance if a T1 relaxation time contrast agent is injected into a subject the phantom compartments may contain different concentrations of that particular contrast agent. However in other embodiments the T1 relaxation time of the calibration phantom is caused by a different T1 relaxation time contrast agent.

In another aspect the invention provides for a magnetic resonance imaging system. The magnetic resonance imaging system comprises a magnet for creating a magnetic field for orienting the magnetic spins of nuclei of a subject located within an imaging volume. The magnetic resonance imaging system further comprises a radio frequency transceiver adapted for acquiring magnetic resonance data using a radio frequency coil. It is understood herein that a reference to a radio frequency transceiver also refers to separate radio frequency transmitter and radio frequency receiver. Likewise the reference to a radio frequency coil also refers to separate transmit and receive radio frequency coils.

The magnetic resonance imaging system further comprises a subject support for receiving a magnetic resonance imaging calibration assembly. The magnetic resonance imaging calibration assembly comprises a subject receptacle for receiving at least a portion of the subject. The magnetic resonance imaging calibration assembly further comprises a plurality of phantom compartments. Each of the plurality of phantom compartments contains a T1 relaxation time calibration phantom with a predetermined T1 relaxation time. The plurality of phantom compartments is located within the imaging volume. The magnetic resonance imaging system further comprises a magnetic field gradient coil adapted for spatial encoding of the magnetic spins of nuclei within the imaging volume. The magnetic resonance imaging system further comprises a magnetic field gradient coil power supply adapted for supplying current to the magnetic field gradient coil.

The magnetic resonance imaging system further comprises a computer system comprising a processor. The computer system is adapted for controlling the magnetic resonance imaging system. For instance the computer system may be interfaced to send and receive control signals to the various components of the magnetic resonance imaging system. The computer system is equivalent to a control system for the magnetic resonance imaging system. The magnetic resonance imaging system further comprises a memory containing machine-readable instructions for execution by the processor.

Execution of the instructions causes the processor to acquire T1-weighted magnetic resonance data using the radio frequency coil. The processor may use the computer system to send control signals to the radio frequency transceiver and the magnetic field gradient coil power supply and in this way received data from the radio frequency transceiver which comprises the magnetic resonance data. Execution of the instructions further causes the processor to reconstruct a T1-weighted magnetic resonance image from the T1-weighted magnetic resonance data. Using Fourier techniques that are well known magnetic resonance data may be reconstructed into a magnetic resonance image. Execution of the instructions further cause the processor to determine a T1 calibration by identifying each of the plurality of phantom compartments in the T1-weighted magnetic resonance image. Each of the plurality of phantom compartments contains a calibration phantom that has a predetermined T1 relaxation time. By identifying the location of the phantom compartments in the magnetic resonance image a calibration can be constructed directly by comparing the intensity at the location of the calibration phantom with the predetermined or known T1 relaxation time.

It is understood herein that references to a magnetic resonance image may also refer to multiple magnetic resonance images. For instance the magnetic resonance data may contain volumetric data. During the reconstruction process the magnetic resonance data may be reconstructed into multiple magnetic resonance images which represent slices of the volume from which the magnetic resonance data was obtained. It should also be noted that as Fourier techniques are used to reconstruct the magnetic resonance images signals from outside of the imaging volume or a specific region of interest may also construct to the reconstruction of a particular image.

In another embodiment each of the plurality of phantom compartments has a distinct cross section. The plurality of phantom compartments is identified at least partially by identifying the distinct cross section in the T1-weighted magnetic resonance image. To accomplish this in some embodiments simple shape recognition or pattern recognition may be used. Since the distinct cross section has a different member of the corners or edges the phantom compartments may be readily identified by known image recognition techniques.

In another embodiment at least one of the phantom compartments comprises a tube. The at least one of the plurality of phantom compartments contains at least two sub-compartments. At least one sub-compartment is not filled with the calibration phantom. The plurality of phantom compartments identified at least partially by detecting the at least one sub-compartment that is not filled in the T1-weighted magnetic resonance image. Again it is noted with reference to the T1-weighted magnetic resonance image may actually refer to multiple images. For instance, if the magnetic resonance data was for a volume which was then later reconstructed into multiple slices or images. This embodiment is advantageous because the sub-compartments which are not filled with the calibration phantom allow a spatial encoding of the various calibration phantoms. This spatial encoding allows simple recognition of the different calibration phantoms.

In another embodiment the plurality of phantom compartments are identified at least partially by the relative position and/or intensity in the T1-weighted magnetic resonance image. When the magnetic resonance imaging calibration assembly is constructed the T1 relaxation time of the plurality of phantom compartments is known. Also the relative location of the various phantom compartments is a known quantity. The magnetic resonance imaging calibration assembly is a mechanical component with the plurality of phantom components fixed to the subject receptacle. Since these geometries are fixed the relative position of the different phantom compartments along with their predetermined T1 relaxation times is known. This knowledge may be used at least partially to identify the location of each of the plurality of phantom compartments. Similarly since the T1-weighted magnetic resonance image will show a different intensity for different phantom compartments depending upon the T1 relaxation time this difference in intensity can also be used to identify the phantom compartments properly. The predetermined T1 relaxation time is known for each of the plurality of phantom compartments. Image recognition software can identify the location of the phantom compartments and then it may be possible to assign the T1 value to each of the phantom compartments by sorting the intensity in the T1-weighted magnetic resonance image.

In another embodiment the instructions further cause the processor to acquire proton-weighted magnetic resonance data. The acquisition of the proton-weighted magnetic resonance data is useful for comparing the calibration phantoms with the magnetic resonance data acquired from the subject. The difference in the proton density can be used in constructing a calibration. The instructions further cause the processor to reconstruct a proton-weighted magnetic resonance image. The instructions further cause the processor to construct a T10 map in accordance with the proton-weighted magnetic resonance image, the T1-weighted magnetic resonance image, and the T1 calibration. The T10 map is essentially a starting or initial T1 map that is used for calibration purposes.

The instructions further cause the processor to acquire post-contrast-agent-T1 -weighted magnetic resonance data. The post-contrast-agent-T1-weighted magnetic resonance data is magnetic resonance data that is acquired after the T1-weighted magnetic resonance data. The post-contrast-agent-T1-weighted magnetic resonance data may for instance be acquired after a T1 contrast agent has been injected into the subject. In some embodiments this may be accomplished automatically by using a delay. For instance after a physician or healthcare professional has injected the subject the physician or healthcare provider may activate a button or control on a graphical user interface on the computer system which starts a timer. In other embodiments the processor may trigger the acquisition after receiving a command from a physician or a healthcare provider for instance through a graphical user interface.

The instructions further cause the processor to reconstruct a post-contrast-agent-T1-weighted magnetic resonance image in accordance with the post-contrast-agent-T1-weighted magnetic resonance data. The instructions further cause the processor to construct a contrast agent concentration map in accordance with the post-contrast-agent-T1-weighted magnetic resonance image, the T10 map and the proton-weighted magnetic resonance image. This embodiment may be extremely advantageous because the contrast agent concentration map which has been constructed may be independent of the scanning system or MRI system which is used. This may be advantageous to simply acquiring pre and post-contrast agent T1-weighted magnetic resonance images and subtracted them.

In another aspect the invention provides for a computer program product comprising machine executable instructions for execution by a processor of a magnetic resonance imaging system according to an embodiment of the invention. Execution of the instructions causes the processor to acquire T1-weighted magnetic resonance data using the radio frequency coil. Execution of the instructions further causes the processor to reconstruct a T1-weighted magnetic resonance image from the T1-weighted magnetic resonance data. Execution of the instructions further cause the processor to determine a T1 calibration by identifying each of the plurality of phantom compartments in the T1-weighted magnetic resonance image. The computer program product may for instance be stored on a computer-readable storage medium. As such embodiments of the invention also provide for a computer-readable storage medium containing the computer program product.

In another aspect the invention provides for a computer-implemented method of determining a T1 calibration. Execution of the method by a magnetic resonance imaging system according to an embodiment of the invention comprises the step of acquiring a T1-weighted magnetic resonance data using the radio frequency coil. The method further comprises the step of reconstructing a T1-weighted magnetic resonance image from the T1-weighted magnetic resonance data. The method further comprises the step of determining the T1 calibration by identifying each of the plurality of phantom compartments in the T1-weighted magnetic resonance image.

### BRIEF DESCRIPTION OF THE DRAWINGS

In the following preferred embodiments of the invention will be described, by way of example only, and with reference to the drawings in which:

FIG. 1 shows a flow diagram which illustrates a method according to an embodiment of the invention;

FIG. 2 shows a flow diagram which illustrates a method according to a further embodiment of the invention;

FIG. 3 shows a flow diagram which illustrates a method according to a further embodiment of the invention;

FIG. 4 illustrates an example of a magnetic resonance calibration assembly according to an embodiment of the invention;

FIG. 5 illustrates an example of a magnetic resonance calibration assembly according to a further embodiment of the invention;

FIG. 6 shows examples of profiles that may be used for phantom compartments;

FIG. 7 illustrates the spatial encoding of phantom compartments using empty and filled sub-compartments of the calibration phantom;

FIG. 8 illustrates an example of a magnetic resonance calibration assembly according to a further embodiment of the invention;

FIG. 9 illustrates an example of a magnetic resonance imaging system according to an embodiment of the invention;

FIG. 10 shows T1 and T2 weighted magnetic resonance images using a magnetic resonance calibration assembly according to an embodiment of the invention; and

FIG. 11 shows a comparison of subtraction images and contrast agent concentration maps.

### DETAILED DESCRIPTION OF THE EMBODIMENTS

Like numbered elements in these figures are either equivalent elements or perform the same function. Elements which have been discussed previously will not necessarily be discussed in later figures if the function is equivalent.

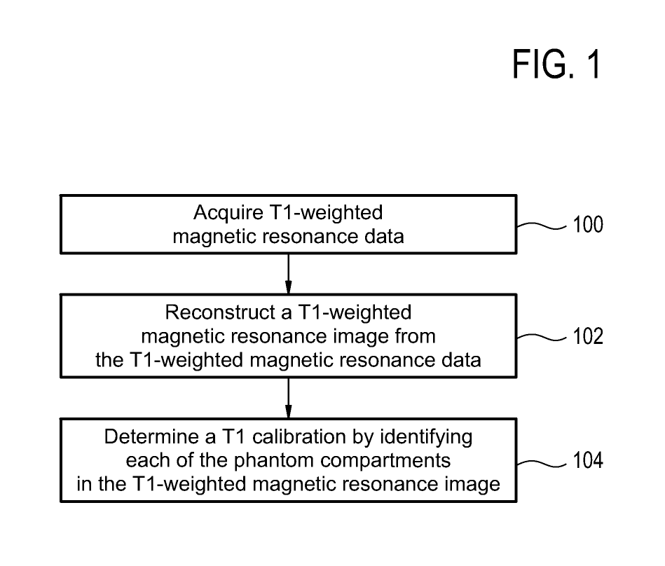

FIG. 1 shows a flow diagram which illustrates a method according to an embodiment of the invention. In step 100 T1-weighted magnetic resonance data is acquired. In step 102 a T1-weighted magnetic resonance image is reconstructed from the T1-weighted magnetic resonance data. Then in step 104 a T1 calibration is determined by identifying each of the phantom compartments in the T1-weighted magnetic resonance image.

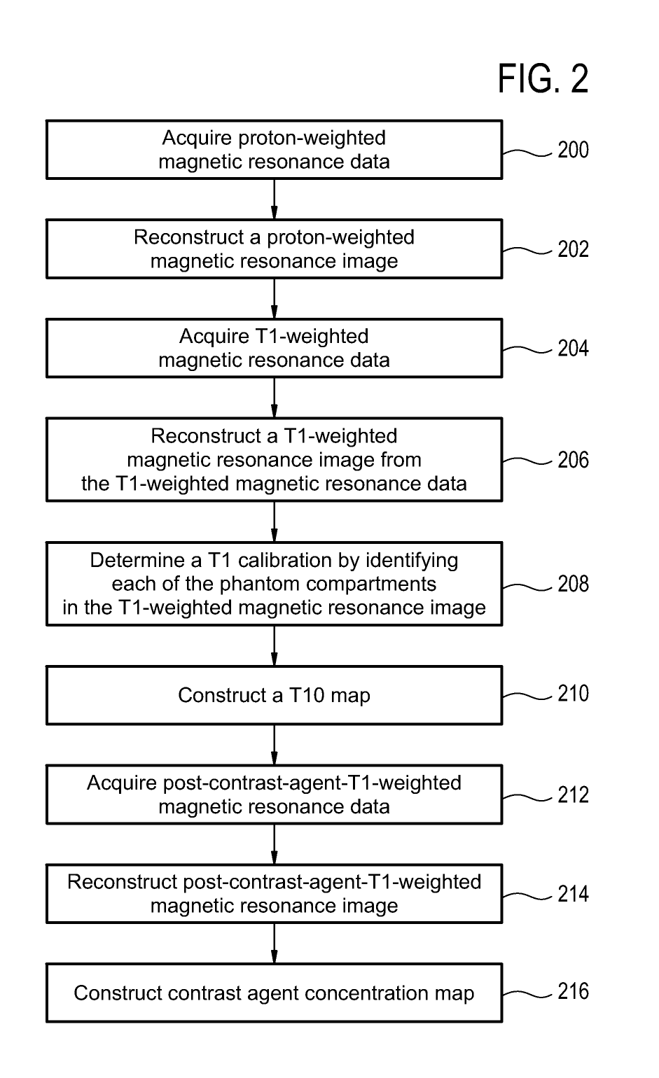

FIG. 2 shows a flow diagram which illustrates a method according to a further embodiment of the invention. In step 200 proton-weighted magnetic resonance data is acquired. In step 202 a proton-weighted magnetic resonance image is reconstructed. In step 204 T1-weighted magnetic resonance data is acquired. In step 206 a T1-weighted magnetic resonance image is reconstructed from the T1-weighted magnetic resonance data. In step 208 a T1 calibration is determined by identifying each of the phantom compartments in the T1-weighted magnetic resonance image. In step 210 a T10 map is constructed. The T10 map is constructed using the proton-weighted magnetic resonance image, the T1-weighted magnetic resonance image and the T1 calibration. In step 212 a post-contrast-agent-T1-weighted magnetic resonance data is acquired. In step 214 a post-contrast-agent-T1-weighted magnetic resonance image is reconstructed using the post-contrast-agent-T1-weighted magnetic resonance data. Finally in step 216 a contrast agent concentration map is constructed. The contrast agent concentration map is constructed using the post-contrast-agent-T1-weighted magnetic resonance image, the T10 map and the proton-weighted magnetic resonance image.

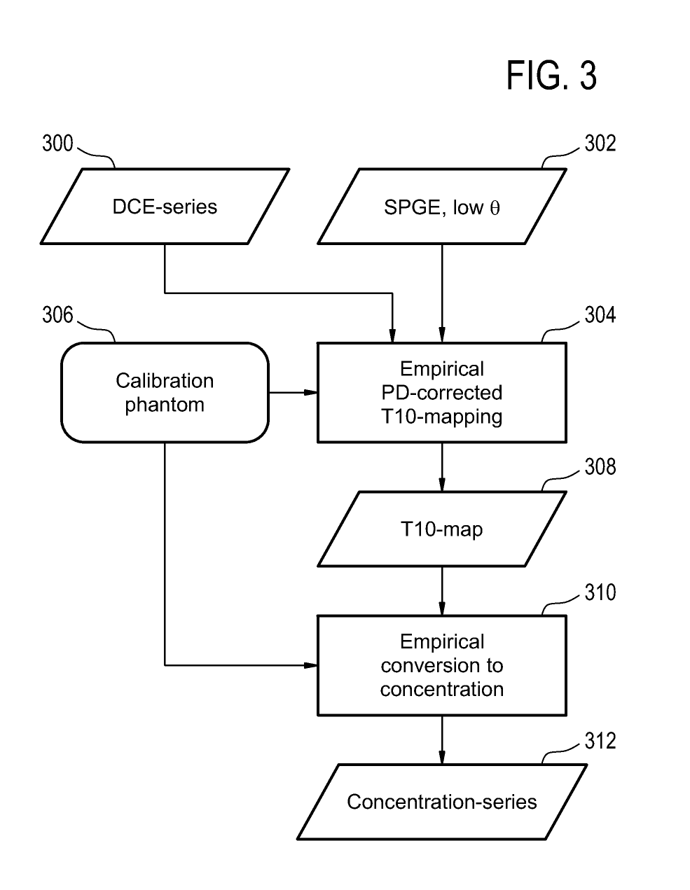

FIG. 3 shows a flow diagram which illustrates a further embodiment of the invention. In block 300 a series of dynamic contrast enhanced MRI images are acquired. These may be images for instance acquired at various times after a T1 relaxation time contrast agent has been injected into a subject. In block 302 an image acquired with a spoiled gradient echo sequence (SPGE) is acquired with a low tip angle. The data from blocks 300 and 302 are combined in block 304 with data obtained from a calibration phantom 306 according to an embodiment of the invention. In block 304 there is an empirical correction for the proton density and a T10 map is constructed. Block 308 after block 304 represents the T10 map. In block 310 there is an empirical conversion to concentration of the calibration. In block 312 further magnetic resonance imaging data is acquired and the empirical calibration is used to direct a series of concentration maps which map the concentration of the contrast agent within a subject over a period of time.

The relevant steps that are illustrated in FIG. 3 are:

1. Detection of the phantom, and phantom compartments.
We obtain intensity values at each time instance in the dynamic scan, for each of the compartments of the phantom, either interactively or supported by an algorithm.
2. Computation of proton density.
The dynamic images are corrected for proton density. For this purpose, a proton weighted additional scan is made (e.g. a spoiled gradient echo acquisition acquired with a low flip angle). The dynamic images can be corrected using:

$$\text{?} = \text{?} = \text{?} . \\ \text{?} \text{indicates text missing or illegible when filed}$$

In an embodiment, we could use the phantom to calibrate proton density, e.g. by using the phantom compartments as a gold standard for 100% proton density. Calibrated proton density maps may have diagnostic value.
3. Computation of T10 maps.
The pre-contrast dynamic images are converted into T1 maps (hence T10 maps). We make use of the following relationship:

S·T₁≈constant,

which, when we compare a voxel with a reference tissue, leads to the relationship:

$$\frac{{S}_{tissue}}{{S}_{ref}} \approx \frac{{T}_{1. ref}}{{T}_{1. tissue}} ,$$

which, using the phantom as a reference tissue of known T1, allows us to compute T10 maps. This approach works well for low contrast agent concentrations (<1 mM), as typically found in tissue. For higher concentrations it becomes less accurate.
4. Computation of a contrast agent concentration map.
We now have T10 maps that show the initial T1 of the tissue. When can use the other images of the dynamic scan to compute T1 maps after the contrast agent has been administered. We can then compute the change in relaxivity (R=1/T1) and use this equation:

ΔR₁(t)=R₁(t)−R₁₀=r₁·C(t),

to compute the contrast agent concentration. In this equation, which r1 (mM⁻¹s⁻¹) is the longitudinal relaxivity and C(t) (mM) the contrast agent concentration.

In an embodiment, instead of using a linear relationship in steps 3 and 4, we can fit a curve to the signal versus contrast relationship in the various compartments of the phantom.

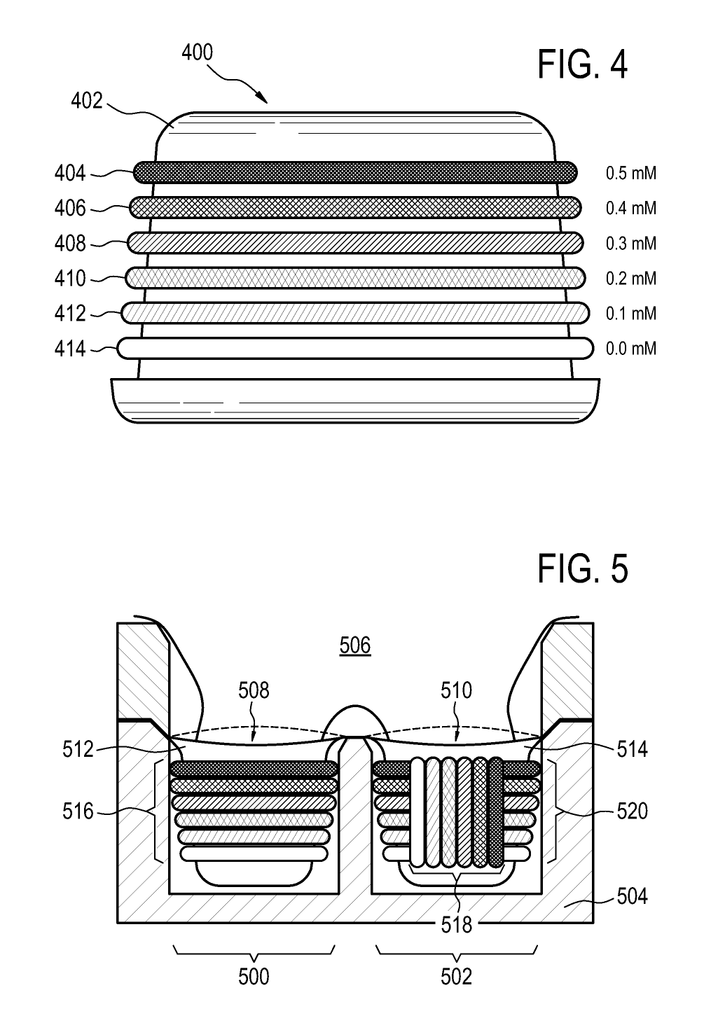

FIG. 4 shows an embodiment of a magnetic resonance imaging calibration assembly 400 according to an embodiment of the invention. The magnetic resonance imaging calibration assembly comprises a subject receptacle 402. In this case the subject receptacle 402 is a cup-shaped plastic piece. Surrounding the subject receptacle 402 is a collection of phantom compartments 404, 406, 408, 410, 412, 414. Each of the phantom compartments 404, 406, 408, 410, 412, 414 is a tube which forms a closed circuit and is filled with distilled water solutions containing various concentrations of the T1 relaxation phantom Gd-DTPA manufactured by Omniscan. The concentration in phantom compartment 404 is a 0.5 mM concentration. The concentration in phantom compartment 406 is a 0.4 mM concentration. The concentration in the phantom compartment 408 is a 0.3 mM concentration. The concentration in phantom compartment 410 is a 0.2 mM concentration. The concentration in phantom compartment 412 is a 0.1 mM concentration. The concentration in phantom compartment 414 is a 0.0 mM concentration.

FIG. 5 shows a diagram with a first magnetic resonance imaging calibration assembly 500 and a second magnetic resonance imaging calibration assembly 502. Both the first magnetic resonance imaging calibration assembly 500 and the second magnetic resonance imaging calibration assembly 502 are located within a subject support 504. Also shown in the Fig. is a subject 506 which has a first breast 508 and a second breast 510. The first breast 508 is shown as being at least partially within the first magnetic resonance imaging calibration assembly 500. The second breast 510 is shown as being within at least partially the second magnetic resonance imaging calibration assembly 502. The first magnetic resonance imaging calibration assembly 500 has a first subject receptacle 512. The second magnetic resonance imaging calibration assembly 502 has a second subject receptacle 514. The first breast 508 is partially located within the first subject receptacle. The second breast 510 is located within the second subject receptacle 514.

Surrounding the first subject receptacle 512 is a plurality or a collection of phantom compartments 516. In this embodiment the phantom compartments 516 are tubes which surround the first subject receptacle 512 horizontally.

The second magnetic resonance imaging calibration assembly 502 shows an alternative embodiment. In the second magnetic resonance imaging calibration assembly there are two groups of phantom compartments 518, 520. First there is a vertical group of phantom compartments 518 which are tubes which are arranged vertically. Adjacent to the vertical phantom compartments 518 are a collection of horizontal phantom compartments 520.

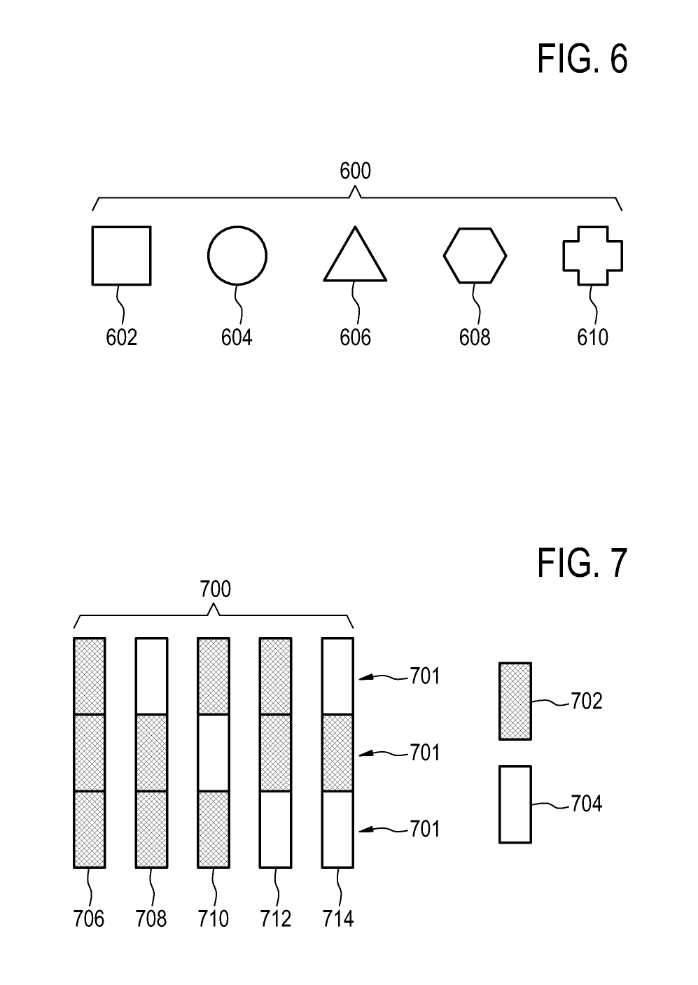

FIG. 6 shows a collection of cross sections 600 which may be used to distinguish different phantom compartments. Amongst the cross section 600 is a square 602, a circle 604, a triangle 606, a hexagon 608, and a plus shape 610. These are examples of shapes which may be easily identifiable in a magnetic resonance image. It will be noted that each of these shapes has a different number of corners. If the magnetic resonance imaging slice goes through the cross section at an oblique angle then the shapes will be distorted. However, the distortion would not affect many image recognition algorithms. For instance an algorithm could simply count the number of corners and distinguish all of these shapes. The shapes shown in FIG. 6 are illustrative and do not form a complete set of distinct cross sections. One skilled in the art will recognize that other shapes are also possible.

FIG. 7 shows a collection of phantom compartments 700. Each of the phantom compartments 700 is divided into three sub-compartments 701. Shaded sub-compartments represent a filled sub-compartment 702. A filled sub-compartment 702 is a sub-compartment filled with a calibration phantom with a predetermined T1 relaxation time. There are also un-shaded sub-compartments 704 which represent empty sub-compartments 704. Empty sub-compartments are not filled with a calibration phantom. Dividing the phantom compartments 700 into individual sub-compartments 701 has the advantage that there can be a spatial encoding of the individual phantom compartments. An example of such a code can be developed by examining FIG. 7. For instance if the filled compartments 702 represent 1 and the empty compartments represent a 0 a code can be developed. For instance phantom compartment 706 has three filled compartments. The code for this would then be the binary code 111. Phantom compartment 708 has a first sub-compartment which is not filled and then two filled compartments. The binary code would then be 011. Following this example the code for phantom compartment 710 would be 101. The code for phantom compartment 712 would be 110. Finally the code for phantom compartment 714 would be 010. By examining one or more magnetic resonance imaging images the spatial code for a particular phantom compartment could be deduced. This could be used to identify or partially identify a phantom compartment in a magnetic resonance image or in a series of magnetic resonance images.

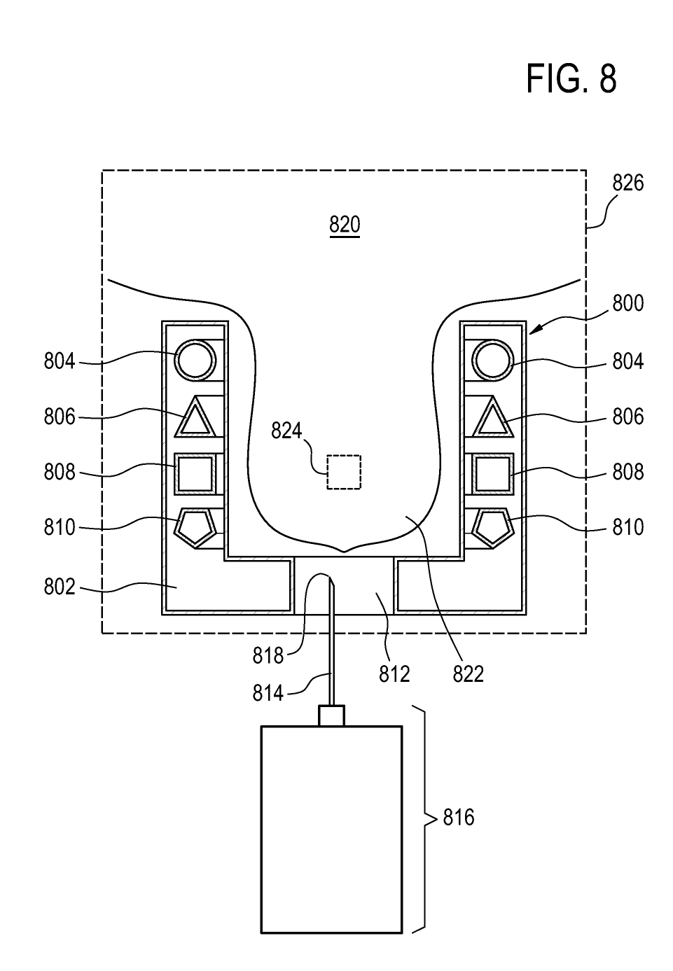

FIG. 8 shows a further embodiment of a magnetic resonance imaging calibration assembly 800. This magnetic resonance imaging calibration assembly 800 comprises a subject receptacle 802. Within the subject receptacle 802 there is a first phantom compartment 804, a second phantom compartment 806, a third phantom compartment 808, and a fourth phantom compartment 810. The view shown in FIG. 8 is a cross sectional view. The first phantom compartment has a circular cross section. The second phantom compartment 806 has a triangular cross section. The third phantom compartment 808 has a square cross section. The fourth phantom compartment 810 has a pentagonal cross section. In this embodiment there is a hole 812 at the bottom of the subject receptacle 802. Located below the hole 812 is a biopsy needle 814 which is connected to a mechanism 816 which is able to actuate the biopsy needle 814. The biopsy needle 814 has a tip 818. Also shown is a subject 820 which has a breast 822 within the subject receptacle 802. Within the breast 822 is a biopsy zone 824. The biopsy zone 824 is a zone for which a physician or healthcare professional would like to perform a biopsy using the biopsy needle 814.

The dashed box 826 represents an imaging zone 826 of a magnetic resonance imaging system. The Fig. shown in FIG. 8 illustrates how the magnetic resonance imaging calibration assembly 800 can be used to guide the biopsy needle 814. After a magnetic resonance image is acquired the biopsy zone 824 may be located by a medical or healthcare professional in a magnetic resonance image. The position of the biopsy zone 824 is known relative to the phantom compartments 804, 806, 808, 810. The location of the tip of the biopsy needle 818 is also known relative to the phantom compartments 804, 806, 808, 810. This is because both the phantom compartments 804, 806, 808, 810 and the mechanism 816 and the biopsy needle 814 form a known mechanical assembly. The location of the phantom compartments 804, 806, 808, 810 relative to the tip 818 of the biopsy needle 814 can be used to send instructions to the mechanism 816 to guide the tip 818 of the biopsy needle 814 to the biopsy zone 824 to perform the biopsy.

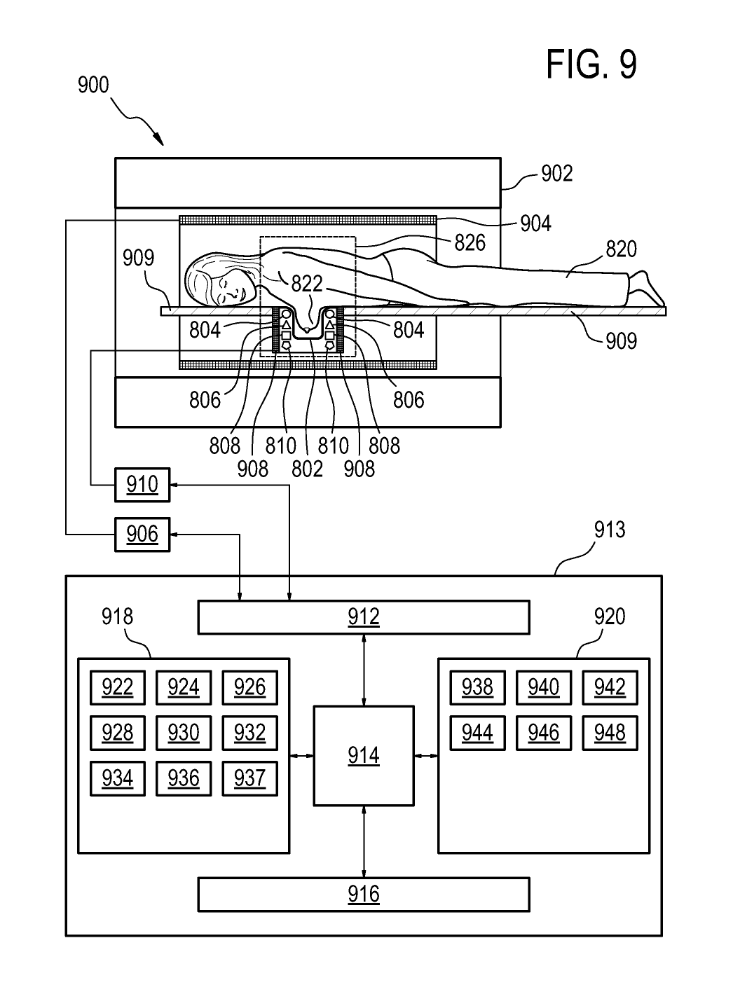

FIG. 9 shows an example of a magnetic resonance imaging system 900 according to an embodiment of the invention. A cross sectional view of the magnet 902 is shown. Within the bore of the magnet there is a magnetic field gradient coil 904. It is understood that the magnetic field gradient coil 904 represents three sets of magnetic field gradient coils for encoding in three different spatial dimensions. Connected to the magnetic field gradient coil is a magnetic field gradient coil power supply which supplies current for energizing the magnetic field gradient coil. Within the bore of the magnet 902 is an imaging zone 826 which is a region which has a magnetic field uniform enough for acquiring magnetic resonance imaging data. Within the imaging zone are shown a radio frequency coil 908 for acquiring magnetic resonance data. The radio frequency coil is connected to a radio frequency transceiver 910. Also within the bore of the magnet 902 is a subject support 909. On the subject support there is a subject 920. A breast 822 of the subject 820 is located within the subject receptacle 802 of a magnetic resonance imaging calibration assembly 800. The magnetic field gradient coil power supply 906 and the radio frequency transceiver 910 are connected to the hardware interface 912 of a computer system 913. The computer system 913 also comprises a processor 914 which is connected to the user interface 912. The processor is also connected to a user interface 916, computer storage 918 and computer memory 920.

In some embodiments the radio-frequency coil 908 may be integrated into the magnetic resonance imaging calibration assembly 800. In some embodiments the magnetic resonance imaging calibration assembly 800 and the subject support 909 may be integrated into a single component. In other embodiments the magnetic resonance imaging calibration assembly 800 may be removable from the subject support 909.

The storage 918 is shown as containing T1-weighted magnetic resonance data 922, T1-weighted magnetic resonance image 924, a T1 calibration 926, a proton-weighted magnetic resonance data 928, a proton-weighted magnetic resonance image 930, a post-contrast-agent-T1-weighted magnetic resonance data 932, a post-contrast-agent-T1-weighted magnetic resonance image 934, a contrast agent concentration map 936, and an T10 map. The computer memory 920 is shown as containing computer executable code for operating and controlling the magnetic resonance imaging system 900. The computer memory is shown as containing a magnetic resonance imaging system control module 938. The magnetic resonance imaging system control module 938 contains computer executable code for controlling the operation and functioning of the magnetic resonance imaging system.

The computer memory is also shown as containing a magnetic resonance image reconstruction module 940. The magnetic resonance image reconstruction module contains computer executable code which is able to reconstruct magnetic resonance data into a magnetic resonance image. For instance the magnetic resonance reconstruction module 940 is able to reconstruct the T1-weighted magnetic resonance data 922 into the T1-weighted magnetic resonance image 924. Likewise module 940 can reconstruct the proton-weighted magnetic resonance data 928 into the proton-weighted magnetic resonance image 930. The magnetic resonance image reconstruction module 940 is also able to reconstruct the post-contrast-agent-T1-weighted magnetic resonance data into the post-contrast-agent-T1-weighted magnetic resonance image 934.

Also shown within the computer memory is the phantom compartment recognition module 942. Depending on the type of phantom compartments 804, 806, 808, 810 the phantom compartment recognition module 942 may be able to recognize different types of phantom compartments. If different cross sections are used the phantom compartment recognition module may be able to recognize the cross sections. If the phantom compartments are spatially encoded the phantom compartment recognition module 942 may be able to detect the spatial encoding to recognize the phantom compartments. The computer memory 920 is also shown as containing a T1 calibration module 944. The T1 calibration module 944 is able to use the phantom compartment recognition module 942 and the T1-weighted magnetic resonance image 924 to construct the T1 calibration 926. The memory is also shown as containing a T10 map construction module 946. The T10 map construction module 946 is able to use the proton-weighted magnetic resonance image 930, the T1-weighted magnetic resonance image 924 and the T1 calibration 926 to construct the T10 map 937. Also shown with the memory is a contrast agent concentration map construction module 948. The contrast agent concentration map construction module 948 is able to construct the contrast agent concentration map 936 using the post-contrast-agent-T1-weighted magnetic resonance image 934, the T10 map 937 and the proton-weighted magnetic resonance image 930.

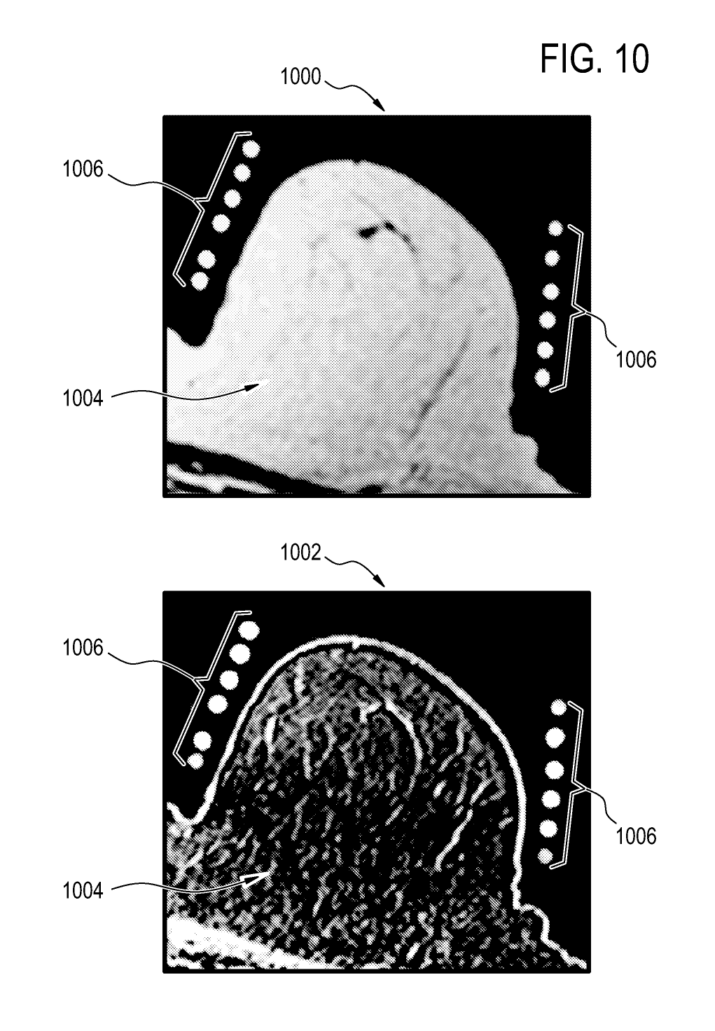

FIG. 10 shows a T2-weighted image 1000 and a T1-weighted image 1002. Within both images a breast 1004 is visible and also images of the phantom compartments 1006. The phantom illustrated in FIG. 4 was used to generate these images. The difference in intensity of the phantom compartments 1006 is visible in FIG. 10.

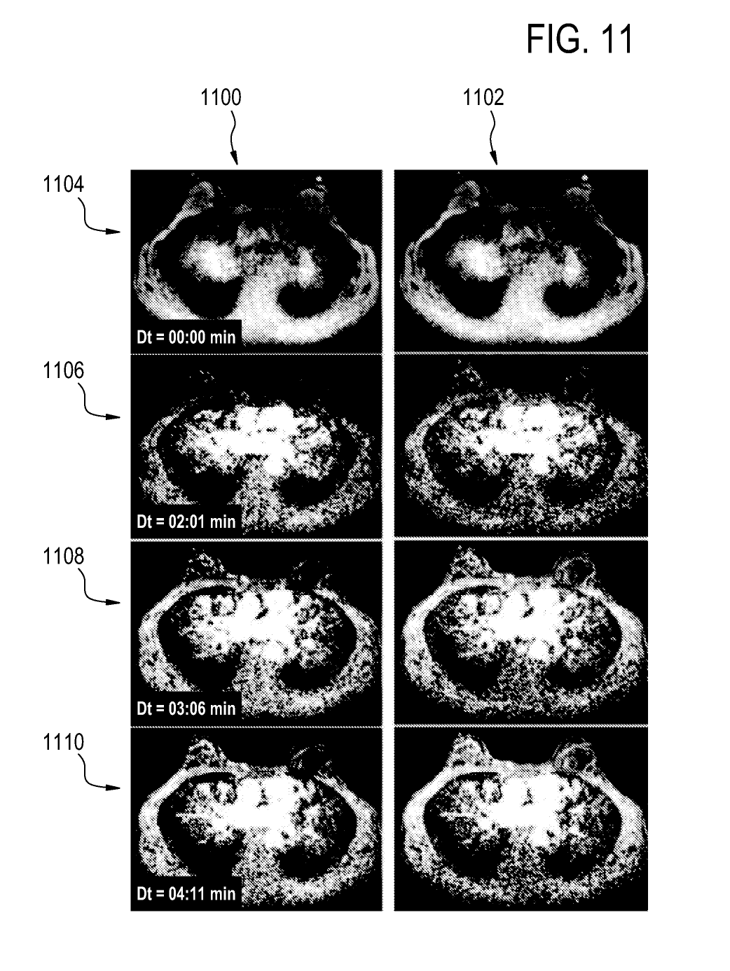

FIG. 11 shows two time series of images on the left the images 1100 show DCE-MRI image constructed using the classical intensity subtraction images. The images on the right are contrast agent concentration maps 1102 calculated from the same data. The images are at different times. The images marked 1104 are at the initial time t=0 seconds. The images marked 1106 are at the t=121 seconds. The images marked 1108 are at the time t=186 seconds. The images marked 1110 are at the time t=251 seconds. These figures show that both the subtraction images 1100 and the contrast agent concentration maps 1102 show similar data. The contrast agent concentration maps 1102 have the advantage that they will be independent of the magnetic resonance imaging system used. In addition the contrast agent concentration maps 1102 show empirically calibrated contrast agent concentrations.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

### LIST OF REFERENCE NUMERALS

400 magnetic resonance imaging calibration assembly
402 subject receptacle
404 phantom compartment 0.5 mM concentration
406 phantom compartment 0.4 mM concentration
408 phantom compartment 0.3 mM concentration
410 phantom compartment 0.2 mM concentration
412 phantom compartment 0.1 mM concentration
414 phantom compartment 0.0 mM concentration
500 first magnetic resonance imaging calibration assembly
502 second magnetic resonance imaging calibration assembly
504 subject support
506 subject
508 first breast
510 second breast
512 first subject receptacle
514 second subject receptacle
516 phantom compartments
518 vertical phantom compartments
520 horizontal phantom compartments
600 cross sections
602 square
604 circle
606 triangle
608 hexagon
610 plus shape
700 phantom compartments
701 sub compartments
702 filled sub compartment
704 empty sub compartment
706 phantom compartment
708 phantom compartment
710 phantom compartment
712 phantom compartment
714 phantom compartment
800 magnetic resonance imaging calibration assembly
802 subject receptacle
804 first phantom compartment
806 second phantom compartment
808 third phantom compartment
810 fourth phantom compartment
812 hole
814 biopsy needle
816 mechanism
818 tip of biopsy neele
820 subject
822 breast
824 biopsy zone
826 imaging zone
900 magnetic resonance imaging system
902 magnet
904 magnetic field gradient coil
906 magnetic field gradient coil power supply
908 radio-frequency coil
909 subject support
910 radio frequency transceiver
912 hardware interface
913 computer system
914 processor
916 user interface
918 storage
920 memory
922 T1-weighted magnetic resonance data
924 T1-weighted magnetic resonance image
926 T1 calibration
928 proton-weighted magnetic resonance data
930 proton-weighted magnetic resonance image
932 post-contrast-agent-T1-weighted magnetic resonance data
934 post-contrast-agent-T1-weighted magnetic resonance image
936 contrast agent concentration map
937 T10 map
938 magnetic resonance imaging system control module
940 magnetic resonance image reconstruction module
942 phantom compartment recognition module
944 T1 calibration module
946 T10 map construction module
948 contrast agent concentration map construction module
1000 T2-weighted image
1002 T1-weighted image
1004 breast
1006 phantom compartments

1. A magnetic resonance imaging contrast agent concentration calibration assembly for use in contrast agent enhanced T1 imaging, comprising:
a subject receptacle for receiving at least a portion of a subject; and
a plurality of identifiable phantom compartments wherein each of the plurality of phantom compartments contains a calibration phantom with a predetermined T1 relaxation time, wherein the plurality of phantom compartments contain various concentrations of the calibration phantom, and wherein the plurality of phantom compartments are attached to the subject receptacle.

2. The magnetic resonance imaging calibration assembly of claim 1, wherein each of the plurality of phantom compartments has a distinct cross section.

3. The magnetic resonance imaging calibration assembly of claim 1, wherein at least one of the plurality of phantom compartments comprises a tube.

4. The magnetic resonance imaging calibration assembly of claim 3,. wherein the at least one of the plurality of phantom compartments contains at least two sub compartments, and wherein at least one sub compartments is not filled with the T1 relaxation time calibration phantom.

5. The magnetic resonance imaging calibration assembly of claim 3, wherein the tube forms a closed circuit.

6. The magnetic resonance imaging calibration assembly of claim 1, comprising a radio frequency coil for acquiring magnetic resonance signals, in particular the radio frequency coil being integrated in the subject receptacle,

7. The magnetic resonance imaging calibration assembly of claim 1, wherein the magnetic resonance imaging calibration assembly further comprises a biopsy apparatus for performing a biopsy of a biopsy zone of the subject, and wherein the biopsy apparatus has a known geometry relative to the plurality of phantom compartments.

8. The magnetic resonance imaging calibration assembly of claim 1, wherein the predetermined T1 relaxation time is equivalent to a known T1 contrast agent concentration.

9. A magnetic resonance imaging system for contrast agent enhanced T1 imaging, comprising:
a magnet for generating a magnetic field for orientating the magnetic spins of nuclei of a subject located within an imaging volume;
a radio frequency transceiver adapted for acquiring magnetic resonance data using a radio frequency coil;
a subject support for receiving a magnetic resonance imaging contrast agent concentration calibration assembly, wherein the magnetic resonance imaging calibration assembly comprises a subject receptacle for receiving at least a portion of the subject, wherein the magnetic resonance imaging calibration assembly further comprises a plurality of identifiable phantom compartments, wherein the plurality of phantom compartments contain various concentrations of the calibration phantom, wherein each of the plurality of phantom compartments contains a calibration phantom with a predetermined T1 relaxation time, wherein the plurality of phantom compartments are located within the imaging volume;
a magnetic field gradient coil adapted for spatial encoding of the magnetic spins of nuclei within the imaging volume;
a magnetic field gradient coil power supply adapted for supplying current to the magnetic field gradient coil;
a computer system comprising a processor, wherein the computer system is adapted for controlling the magnetic resonance imaging system; and
a memory containing machine readable instructions for execution by the processor, wherein execution of the instructions cause the processor to:
acquire T1-weighted magnetic resonance data using the radio frequency coil;
reconstruct a T1-weighted magnetic resonance image from the T1-weighted magnetic resonance data;
determine a T1 calibration by indentifying each of the plurality of phantom compartments in the T1-weighted magnetic resonance image.

10. The magnetic resonance imaging system of claim 9, wherein each of the plurality of phantom compartments has a distinct cross section, wherein the plurality of phantom compartments are identified at least partially by identifying the distinct cross section in the T1-weighted magnetic resonance image,

11. The magnetic resonance imaging system of claim 9, wherein at least one of the plurality of phantom compartments comprises a tube, wherein the at least, one of the plurality of phantom compartments contains at least, two sub compartments, wherein at least one sub compartment is not filled with the T1 relaxation time calibration phantom, wherein the plurality of phantom compartments are identified at least partially by detecting the at least one sub compartment that is not filled in the T1-weighted magnetic resonance image,

12. The magnetic resonance imaging system of claim 9, wherein the plurality of phantom compartments are identified at least partially by their relative position and/or intensity in the T1-weighted magnetic resonance image,

13. The magnetic resonance imaging system of claim 9 wherein, the instructions further cause the processor to:
acquire proton-weighted magnetic resonance data;
reconstruct a proton-weighted magnetic resonance image;
construct a T10 map in accordance with the proton-weighted magnetic resonance image, the T1-weighted weighted magnetic resonance image, and the T1 calibration;
acquire post-contrast-agent-T1-weighted magnetic resonance data;
reconstruct a post-contrast-agent-T1-weighted magnetic resonance image in accordance with the post-contrast-agent-T1-weighted magnetic resonance data; and
construct a contrast agent concentration map in accordance with the post-contrast-agent-T1-weighted magnetic resonance image, the T10 map, and the proton-weighted magnetic resonance image,

14. A computer program product comprising machine executable instructions for execution by a processor of a magnetic resonance imaging system according to claim 10; wherein execution of the instructions cause the processor to:
acquire T1-weighted magnetic resonance data using the radio frequency coil;
reconstruct a T1-weighted magnetic resonance image from the T1-weighted magnetic resonance data;
determine a T1 calibration by indentifying each of the plurality of phantom compartments in the T1-weighted magnetic resonance image.

15. A computer-implemented method of determining a T1 calibration, wherein execution of the method by a magnetic resonance imaging system according to claim 10 comprises the steps of:
acquiring T1-weighted magnetic resonance data using the radio frequency coil;
reconstructing a T1-weighted magnetic resonance image from the T1-weighted magnetic resonance data;
determining the T1 calibration by indentifying each of the plurality of phantom compartments in the T1-weighted magnetic resonance image.
